(19) United States
(12) Patent Application Publication
(10) Pub. No.: US 2016/0141020 A1
(43) Pub. Date: May 19, 2016

(54) STATIC RANDOM ACCESS MEMORY FREE FROM WRITE DISTURB AND TESTING METHOD THEREOF

(71) Applicant: MEDIATEK INC., Hsin-Chu (TW)

(72) Inventors: Rei-Fu Huang, Hsinchu City (TW); Shih-Huang Huang, Hsin-Chu City (TW)

(21) Appl. No.: 14/543,910

(22) Filed: Nov. 18, 2014

(51) Int. Cl. G11C 11/418; G11C 29/00; G11C 11/419

(52) U.S. Cl. CPC G11C 11/418; G11C 11/419; G11C 29/00

(57) ABSTRACT

A static random access memory (SRAM) includes a memory cell array, a row decoder, a plurality of word-line drivers and an arbiter. The memory cell array includes a plurality of memory cell rows, wherein the memory cell rows are enabled by a plurality of word-lines, respectively. The row decoder is arranged to assert one of the memory cell rows according to a row address. The plurality of word-line drivers are each coupled to the row decoder and one of the memory cell rows. The arbiter is arranged to prevent multiple memory cells at a same word-line from being accessed at a same time.

### BACKGROUND

This invention relates to solid-state memory. Embodiments of this invention are more specifically directed to an 8-T 2/dual port static random access memory (SRAM) which is free from the “write disturb” phenomenon and a testing method for an 8-T 2/dual port SRAM.

Static random access memory (SRAM) has become the memory technology of choice for solid-state data storage. SRAM cells store contents “statically”; i.e. the stored data state remains latched in each cell so long as power is applied to the memory. This is in contrast to “dynamic” RAM (“DRAM”), in which the data must be periodically refreshed in order to be retained.

Recent advances in semiconductor technology have enabled the shrinking of minimum device feature sizes (e.g. MOS transistor gates) into the sub-micron range. This miniaturization is especially beneficial when applied to memory arrays, as a large proportion of the overall chip area is devoted to on-chip memories. Significant memory resources can now be integrated as embedded memory into larger-scale integrated circuits, such as microprocessors, digital signal processors, and “system-on-a-chip” integrated circuits. This physical scaling of device sizes raises significant issues, however, especially in connection with embedded SRAM, and in SRAMs realized as “stand-alone” memory integrated circuit devices. Several of these issues are due to the increased variability in the electrical characteristics of transistors formed at these extremely small feature sizes. This variability has been observed to increase the likelihood of read and write functional failures, on a cell-to-cell basis. Sensitivity to device variability is especially high in those memories that are at, or near, their circuit design limits. The combination of increased device variability with the larger number of memory cells (and thus transistors) within an integrated circuit renders a high likelihood that one or more cells cannot be read or written as expected.

For example, the conventional 8-T cell is vulnerable to unintentional changes of state during the writing of data to other cells. More specifically, it has been observed that SRAM cells in unselected columns of selected rows (i.e. “half-selected” cells) are especially vulnerable to the “disturb” condition present on their bit lines during writes to cells in the same row, aka “write disturb” . The “disturb” condition may become severe as the semiconductor process is scaled down. March algorithms are the dominant test algorithms implemented in most modern memory BIST because March-based tests are simple and possess good fault coverage. General March algorithms are based on single-port SRAM, however, and cannot screen out chips which fail due to the “disturb” condition.

In light of the above, how to prevent a memory embedded chip from failing on the “disturb” condition and how to screen out a memory embedded chip which may fail on the “disturb” condition has become an important issue in this field.

### SUMMARY

According to a first aspect of the present invention, a static random access memory (SRAM) is disclosed. The SRAM comprises a memory cell array, a row decoder, a plurality of word-line drivers and an arbiter. The memory cell array comprises a plurality of memory cell rows, wherein the memory cell rows are enabled by a plurality of word-lines, respectively. The row decoder is arranged to assert one of the memory cell rows according to a row address. The plurality of word-line drivers are each coupled to the row decoder and one of the memory cell rows. The arbiter is arranged to protect multiple memory cells at a same word-line from being accessed at a same time.

According to a second aspect of the present invention, a method for testing a static random access memory (SRAM) is disclosed, wherein the SRAM comprises a memory cell array with a plurality of memory cell rows, and each memory cell row is enabled by one of a plurality of word-lines. The method comprises: performing a first read operation upon a cell of a first memory cell row of the plurality of memory cell rows; performing a first write operation upon another cell of the first memory cell row in order to write first data into the another cell; and performing a second read operation upon the another cell of the first memory cell row in order to obtain a reading result and verify the reading result according to the first data; wherein an execution time of the first read operation and an execution time of the first write operation at least overlap with each other.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a static random access memory according to an exemplary embodiment of the present invention.

FIG. 2 is a diagram illustrating a modified March-based memory test scheme according to an exemplary embodiment of the present invention.

FIG. 3 is a diagram illustrating a modified March-based memory test scheme according to another exemplary embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

The main concept of the present invention is to avoid erroneous conditions due to the “write disturb” issue while performing read/write operations upon a static random access memory (SRAM). Two exemplary embodiments are disclosed, wherein the first embodiment is a hardware-based mechanism where an incoming operation directed to unselected columns of selected rows (i.e. “half-selected” cells) is forbidden; and the second embodiment is a test plan where “write disturb” is deliberately created to screen out the dies without immunity to “write disturb”. Further details will be described with reference to the accompanying drawings.

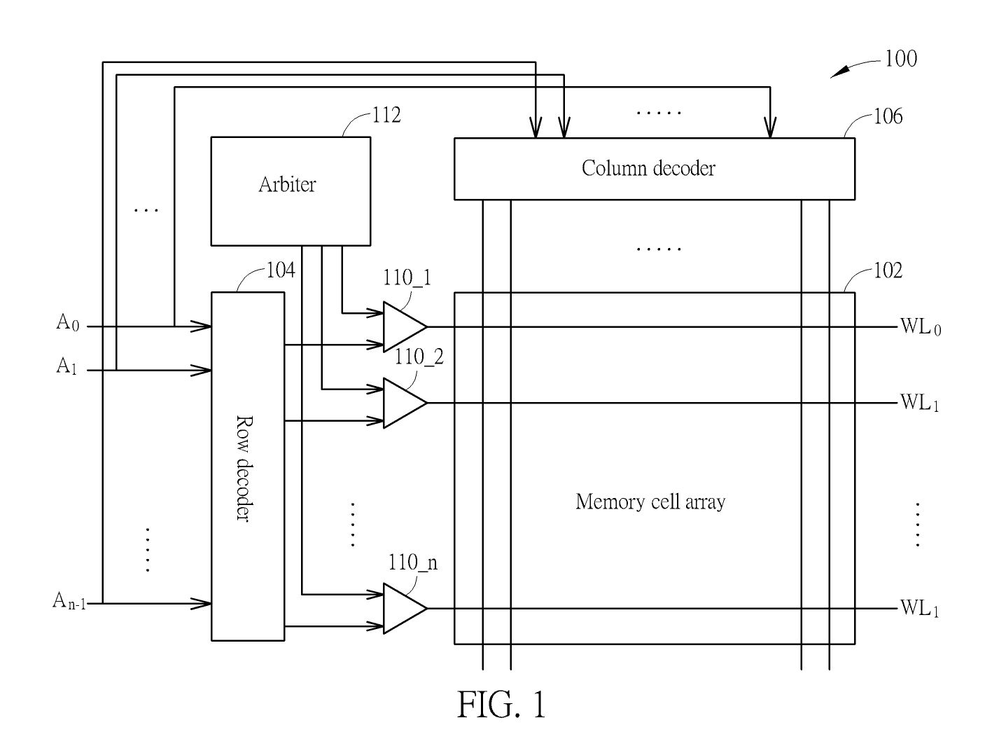

FIG. 1 is a block diagram illustrating a static random access memory according to an exemplary embodiment of the present invention. The static random access memory 100 includes a memory cell array 102, a row decoder 104, a column decoder 106, a plurality of word-line drivers 110_1-110_n, and an arbiter 112. The memory cell array 102 is a two/dual-port 8-T memory cell array, which comprises a plurality of memory cell rows (not shown), wherein each memory cell row is enabled by one of a plurality of word-lines WL₀-WLₙ₋₁. The row decoder 104 is for asserting one of the memory cell rows according to a row address of a memory address [Aₙ₋₁, Aₙ₋₂, . . . A₀] via a corresponding one of the word-line drivers 110_1-110_n, wherein Aₙ₋₁ is the MSB of the memory address; and A₀ is the LSB of the memory address. The column decoder 106 is for asserting one of the memory cell columns according to a column address of the memory address [Aₙ₋₁, Aₙ₋₂, . . . A₀]. Please note that the static random access memory 100 is for illustrative purpose only. In normal cases, the word-lines WL₀-WLₙ₋₁ of the two/dual-port 8-T memory cell array 102 comprise n write word lines and n read word lines; and the detailed circuitry design may vary depending on different specification requirements, and is omitted here for brevity. By collaborating with the row decoder 104, a memory cell belonging to the selected word-line can be configured to store a specified value or output a value stored therein. The major difference between the SRAM 100 and the conventional SRAM is that the arbiter 112 is capable of protecting two memory cells of the memory cell array 102 which share a same word-line from being accessed at the same time, so as actively to avoid the “write disturb” issue.

More specifically, the arbiter disables an incoming write/read operation directed to a memory cell of one of the word-lines WL₀-WLₙ₋₁ until a previous write/read operation directed to another memory cell of the same word-line has been completed. The arbiter 112 disables the incoming write/read operation by disabling the word-line driver responsible for driving the same word-line selected by the previous write/read operation. For example, the arbiter 112 may generate control signals EN₀-ENₙ₋₁ according to the usage condition of the word-lines WL₀-WLₙ₋₁, a signal indicating whether a read operation is completed and another signal indicating whether a write operation is completed. This is for illustrative purposes only, and is not meant to be a limitation of the present invention. In short, the control signals EN₀-ENₙ₋₁ forbid two or more than two write/read operations simultaneously performed upon cells on a same word-line.

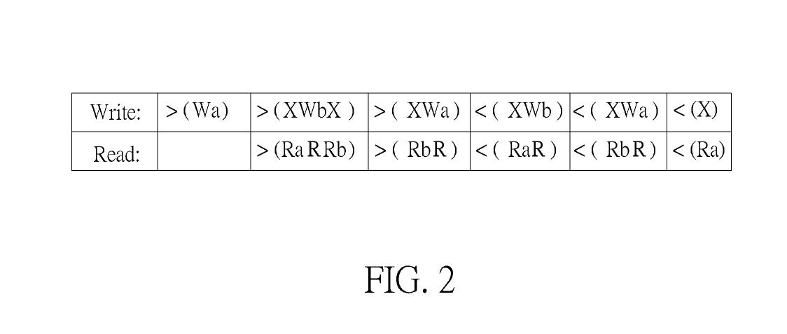

FIG. 2 is a diagram illustrating a modified March-based memory test scheme according to an exemplary embodiment of the present invention. The conventional March-based memory test scheme was originally proposed to deal with single-port SRAM, which only allows one access at a time, and therefore the “write disturb” issue was not considered. If an active “write disturb” prevention mechanism such as the arbiter 112 of the above mentioned SRAM 100 is not embedded, the conventional March-based memory test scheme may fail to screen out those dies which are sensitive or vulnerable to the “disturb” condition present on their bit lines during writes to cells in the same row. Please refer to the modified March-based memory test scheme shown in FIG. 2, where “Wa” is representative of a write operation which writes data (a) into selected cells, and “Wb” is also representative of a write operation which writes data (b), which is an inverse data of data (a), into selected cells. In addition, “Ra” is representative of a read operation which reads data from selected cells and compares the data with the data (a) to verify if successful write & read operations are completed, and “Rb” is representative of a read operation which reads data from selected cells and compares the data with the data (b) to verify if successful write & read operations are completed with respect to an inverse data of the data (a), i.e. the data (b).

Most importantly, according to the present invention, “R” as shown in boldface in FIG. 2, is representative of a dummy read operation which reads data from cells with a memory address which is the same as that of the concurrent “Wa” or “Wb” operation except for the LSB part, i.e. the column address. In this way, two memory cells belonging to a same word-line are accessed simultaneously to testify if the “write disturb” issue can be overcome by checking the value of the cell at the next “Ra” or “Rb” operation. Please note that the dummy read operation “R” may only read data from the selected cells without verification, since the only reason for this operation is to induce the “write disturb” phenomenon for testifying the concurrent “Wa” or “Wb” operation performed on other cells of the same word-line. Lastly, no operation is performed by an “X” notation. Specifically, the modified March-based memory test scheme shown in FIG. 2 is substantially the same as the conventional March-based memory test scheme, except that the dummy read operations “R” are added to intentionally produce the “write disturb” phenomenon. Please note that the modified March-based memory test scheme shown in FIG. 2 may be applied to an 8-T two/dual port memory cell array.

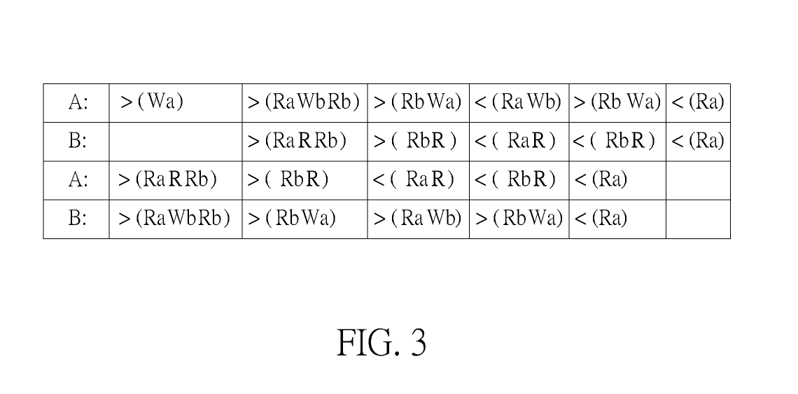

FIG. 3 is a diagram illustrating a modified March-based memory test scheme according to another exemplary embodiment of the present invention. Please note that the modified March-based memory test scheme shown in FIG. 3 maybe applied to an 8-T dual port memory cell array. As a person skilled in the art can readily understand the operation of testifying the 8-T dual port memory cell array after reading the above paragraphs, further description is omitted here for brevity. The principle of the modified March-based memory test scheme shown in FIG. 3 is identical to that shown in FIG. 2, and it should be noted that any other alternative design using the dummy read operation “R” also falls into the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A static random access memory (SRAM), comprising:
a memory cell array, comprising a plurality of memory cell rows, wherein the memory cell rows are enabled by a plurality of word-lines, respectively;
a row decoder, arranged to assert one of the memory cell rows according to a row address;
a plurality of word-line drivers, each coupled to the row decoder and one of the memory cell rows; and
an arbiter, arranged to protect multiple memory cells at a same word-line from being accessed at a same time.

2. The SRAM as claimed in claim 1, wherein when a previous access operation directed to a memory cell of a specific word-line has not been completed, the arbiter stops an incoming access operation directed to another memory cell of the specific word-line.

3. The SRAM as claimed in claim 2, wherein the arbiter is coupled to the word-line drivers; and the arbiter stops the incoming access operation by disabling a word-line driver responsible for driving the specific word-line selected by the previous access operation.

4. The SRAM as claimed in claim 1, wherein the memory cell array is an N-port memory cell array, and N is a positive integer larger than one.

5. The SRAM as claimed in claim 1, wherein the memory cell array is an 8-T memory cell array.

6. A method for testing a static random access memory (SRAM), wherein the SRAM comprises a memory cell array with a plurality of memory cell rows enabled by a plurality of word-lines, respectively, the method comprising:
performing a first read operation upon a cell of a first memory cell row of the plurality of memory cell rows;
performing a first write operation upon another cell of the first memory cell row, to write first data into the another cell; and
performing a second read operation upon another cell of the first memory cell row, to obtain a reading result and verifying the reading result according to the first data;
wherein an execution time of the first read operation and an execution time of the first write operation at least overlap with each other.

7. The method as claimed in claim 6, wherein the memory cell array is an N-port memory cell array, and N is a positive integer larger than one.

8. The method as claimed in claim 6, wherein the memory cell array is an 8-T memory cell array.

9. The method of claim 6, wherein a memory address of the another cell upon which the first write operation is performed is identical to a memory address of the cell upon which the first read operation is performed, except for the column addresses.

10. The method of claim 6, wherein the method is applied to a March-based memory test algorithm.
